(19) United States
(12) Patent Application Publication
(10) Pub. No.: US 2017/0005291 A1
(43) Pub. Date: Jan. 5, 2017

(54) FLEXIBLE DISPLAY AND METHOD OF MANUFACTURING THE SAME

(71) Applicant: Samsung Display Co., Ltd., Yongin-si (KR)

(72) Inventors: Taehyun Sung, Yongin-si (KR); Jongseong Kim, Yongin-si (KR); Hyungu Lee, Yongin-si (KR)

(21) Appl. No.: 15/177,291

(22) Filed: Jun. 8, 2016

(30) Foreign Application Priority Data
Jul. 1, 2015 (KR) 10-2015-0094003

(51) Int. Cl. H01L 51/52; H01L 27/32; H01L 51/56

(52) U.S. Cl. CPC H01L 51/5253; H01L 51/56; H01L 27/3248; H01L 2227/323; H01L 2251/5338; H01L 2251/558

(57) ABSTRACT

A method of manufacturing a flexible display is disclosed. In one aspect, the method includes forming a display panel including first and second sides opposing each other, wherein the display panel includes a plurality of cells in a mother substrate form, and wherein each of the cells includes a display unit. The method also includes attaching a first protection film on the first side of the display panel via a first adhesive layer and attaching a second protection film on the second side of the display panel via a second adhesive layer. The method further includes irradiating laser light having a first wavelength between the cells so as to cut the display panel into the cells. Each of the first and second adhesive layers includes an absorber configured to absorb light having the first wavelength.

### INCORPORATION BY REFERENCE TO ANY PRIORITY APPLICATIONS

This application claims the benefit of Korean Patent Application No. 10-2015-0094003, filed on Jul. 1, 2015, in the Korean Intellectual Property Office, the disclosure of which is incorporated herein in its entirety by reference.

### BACKGROUND

1. Field

The described technology generally relates to a flexible display and a method of manufacturing the same.

2. Description of the Related Technology

Recently, according to increased market demand for flexible displays, research to improve the technology has been actively performed. A flexible display can be used in a display unit of a small product, such as a mobile phone, or a display unit of a large product, such as a television set (small and large form factors).

To manufacture a flexible display, a flexible substrate, such as composite resin, is used rather than a conventional glass substrate. The nature of a flexible substrate requires extra care during the manufacturing process. Accordingly, the flexible substrate is formed on a rigid support substrate to be maintained in a flat state during manufacture.

The support substrate and the flexible substrate are provided in the form of a mother substrate to simultaneously produce multiple flexible display panels and to be cut into separate panels either before or after separation from the support substrate.

However, in a typical manufacturing method, when a cutting process is performed using laser during a separating process, the flexible display panel can be damaged by transmission of the laser, and fumes can be generated.

### SUMMARY OF CERTAIN INVENTIVE ASPECTS

One inventive aspect relates to a flexible display with improved quality and a simplified process and a manufacturing method thereof.

Another aspect is a method of manufacturing a flexible display that may include forming a display panel having one side and the other side opposite to the one side and having a mother substrate form with a plurality of cells each having a display unit, attaching a first protection film on the one side of the display panel through a first adhesive layer disposed therebetween, attaching a second protection film on the other side of the display panel through a second adhesive layer disposed therebetween, and cutting the display panel by irradiating laser having a first wavelength between the cells, wherein the first adhesive layer and the second adhesive layer may include an absorber to absorb light having a same wavelength as the first wavelength.

The cutting of the display panel by irradiating the laser may include cutting the first protection film by irradiating the laser having the first wavelength on the first protection film, cutting the first adhesive layer by irradiating the laser having the first wavelength on the first adhesive layer, cutting the cells by irradiating the laser on an area between the cells, cutting the second adhesive layer by irradiating the laser having the first wavelength on the second adhesive layer, and cutting the second protection film by irradiating the laser having the first wavelength on the second protection film.

The first protection film and the second protection film may have a first thickness, and the first adhesive layer and the second adhesive layer have a second thickness that is same as or greater than the first thickness.

The first thickness may be about 10 μm to about 100 μm, and the second thickness may be about 10 μm to about 200 μm.

The first adhesive layer and the second adhesive layer may include silicone, urethane, or acryl-based adhesive material.

The first wavelength may be a wavelength in an ultraviolet (UV) range.

The first wavelength is a wavelength in an infrared (IR) range.

The first adhesive layer and the second adhesive layer may have a transmittance of about 0.1% to about 1% with respect to light having the first wavelength.

The first protection film and the second protection film may include one material among polyethylene terephthalate (PET), polyethylene naphthalate (PEN), polyethylene sulfide (PES), and polyethylene (PE).

Another aspect is a flexible display that may include a flexible substrate having one side and the other side opposite to the one side, a thin film transistor disposed on the one side of the flexible substrate and a light-emitting device electrically connected to the thin film transistor, a protection film disposed on the other side of the flexible substrate, and an adhesive layer disposed between the flexible substrate and the protection film and having an absorber to absorb light having a first wavelength.

The first wavelength may be a wavelength in an ultraviolet (UV) range.

The first wavelength may be a wavelength in an infrared (IR) range.

The protection film may have a first thickness and the adhesive layer has a second thickness that is same as or greater than the first thickness.

The first thickness may be about 10 μm to about 100 μm, and the second thickness may be about 10 μm to about 200 μm.

The adhesive layer may include silicone, urethane, or acryl-based adhesive material.

The adhesive layer may have transmittance of about 0.1% to about 1% with respect to light having the first wavelength.

The protection film may include one material among polyethylene terephthalate (PET), polyethylene naphthalate (PEN), polyethylene sulfide (PES), and polyethylene (PE).

Another aspect is a method of manufacturing a flexible display, the method comprising: forming a display panel including first and second sides opposing each other, wherein the display panel includes a plurality of cells in a mother substrate form, and wherein each of the cells includes a display unit; attaching a first protection film on the first side of the display panel via a first adhesive layer; attaching a second protection film on the second side of the display panel via a second adhesive layer; and irradiating laser light having a first wavelength between the cells so as to cut the display panel into the cells, wherein each of the first and second adhesive layers includes an absorber configured to absorb light having the first wavelength.

In the above method, the irradiating comprises: irradiating laser light having the first wavelength on the first protection film so as to cut the first protection film; irradiating laser light having the first wavelength on the first adhesive layer so as to cut the first adhesive layer; irradiating laser light on an area between the cells so as to cut the cells; irradiating laser light having the first wavelength on the second adhesive layer; so as to cut the second adhesive layer; and irradiating laser light having the first wavelength on the second protection film so as to cut the second protection film.

In the above method, each of the first and second protection films has a first thickness, wherein each of the first and second adhesive layers has a second thickness that is the same as or greater than the first thickness.

In the above method, the first thickness is about 10 μm to about 100 μm, wherein the second thickness is about 10 μm to about 200 μm.

In the above method, each of the first and second adhesive layers comprises silicone, urethane, or acryl-based adhesive material.

In the above method, the first wavelength is a wavelength in an ultraviolet (UV) range.

In the above method, the first wavelength is a wavelength in an infrared (IR) range.

In the above method, each of the first and second adhesive layers has a transmittance of about 0.1% to about 1% with respect to light having the first wavelength.

In the above method, each of the first and second protection films comprises at least one of the following: polyethylene terephthalate (PET), polyethylene naphthalate (PEN), polyethylene sulfide (PES), and polyethylene (PE).

Another aspect is a flexible display comprising: a flexible substrate including first and second sides opposing each other; a thin film transistor disposed on the first side of the flexible substrate and a light-emitting device electrically connected to the thin film transistor; a protection film disposed on the second side of the flexible substrate; and an adhesive layer disposed between the flexible substrate and the protection film, wherein the adhesive layer includes an absorber configured to absorb light having a first wavelength.

In the above flexible display, the first wavelength is a wavelength in the ultraviolet (UV) spectrum.

In the above flexible display, the first wavelength is a wavelength in the infrared (IR) spectrum.

In the above flexible display, the protection film has a first thickness, wherein the adhesive layer has a second thickness that is the same as or greater than the first thickness.

In the above flexible display, the first thickness is about 10 μm to about 100 μm, wherein the second thickness is about 10 μm to about 200 μm.

In the above flexible display, the adhesive layer comprises silicone, urethane, or acryl-based adhesive material.

In the above flexible display, the adhesive layer has transmittance of about 0.1% to about 1% with respect to light having the first wavelength.

In the above flexible display, the protection film comprises at least one of the following: polyethylene terephthalate (PET), polyethylene naphthalate (PEN), polyethylene sulfide (PES), and polyethylene (PE).

Another aspect is a flexible display comprising: a flexible substrate including first and second sides opposing each other; a protection film disposed on the second side of the flexible substrate; and an adhesive layer disposed between the flexible substrate and the protection film, wherein the adhesive layer includes an absorber configured to absorb light having a non-visible light wavelength.

In the above flexible display, the protection film has a first thickness, wherein the adhesive layer has a second thickness that is the same as or greater than the first thickness.

In the above flexible display, the first thickness is about 10 μm to about 100 μm, wherein the second thickness is about 10 μm to about 200 μm.

### BRIEF DESCRIPTION OF THE DRAWINGS

These and/or other aspects will become apparent and more readily appreciated from the following description of the exemplary embodiments, taken in conjunction with the accompanying drawings.

FIG. 1 is a perspective view schematically illustrating a flexible display in a mother substrate form before cutting the flexible display according to an embodiment.

FIG. 2 is a cross-sectional view taken along a line II-II of FIG. 1.

FIGS. 3 through 7 are cross-sectional views schematically illustrating a cutting process of a manufacturing method of the flexible display, according to an embodiment.

FIG. 8 is an enlarged cross-sectional view illustrating an internal structure of a display panel of the flexible display according to an embodiment.

FIG. 9 is a cross-sectional view schematically illustrating a flexible display according to an embodiment.

FIG. 10 is a cross-sectional view illustrating a structure of a display panel of the flexible display of FIG. 9 in detail.

### DETAILED DESCRIPTION OF CERTAIN INVENTIVE EMBODIMENTS

The present exemplary embodiments may have different forms and should not be construed as being limited to the descriptions set forth herein. Accordingly, the exemplary embodiments are merely described below, by referring to the figures, to explain aspects of the present description.

Reference will now be made in detail to exemplary embodiments, examples of which are illustrated in the accompanying drawings, wherein like reference numerals refer to like elements throughout, and duplicate explanations thereof will be omitted.

It will be understood that although the terms “first”, “second”, etc. may be used herein to describe various components, these components should not be limited by these terms. These components are only used to distinguish one component from another.

Sizes of elements in the drawings may be exaggerated for convenience of explanation. In other words, since sizes and thicknesses of components in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

As used herein, the term “and/or” includes any and all combinations of one or more of the associated listed items. Expressions such as “at least one of,” when preceding a list of elements, modify the entire list of elements and do not modify the individual elements of the list. In this disclosure, the term “substantially” includes the meanings of completely, almost completely or to any significant degree under some applications and in accordance with those skilled in the art. Moreover, “formed, disposed or positioned over” can also mean “formed, disposed or positioned on.” The term “connected” includes an electrical connection.

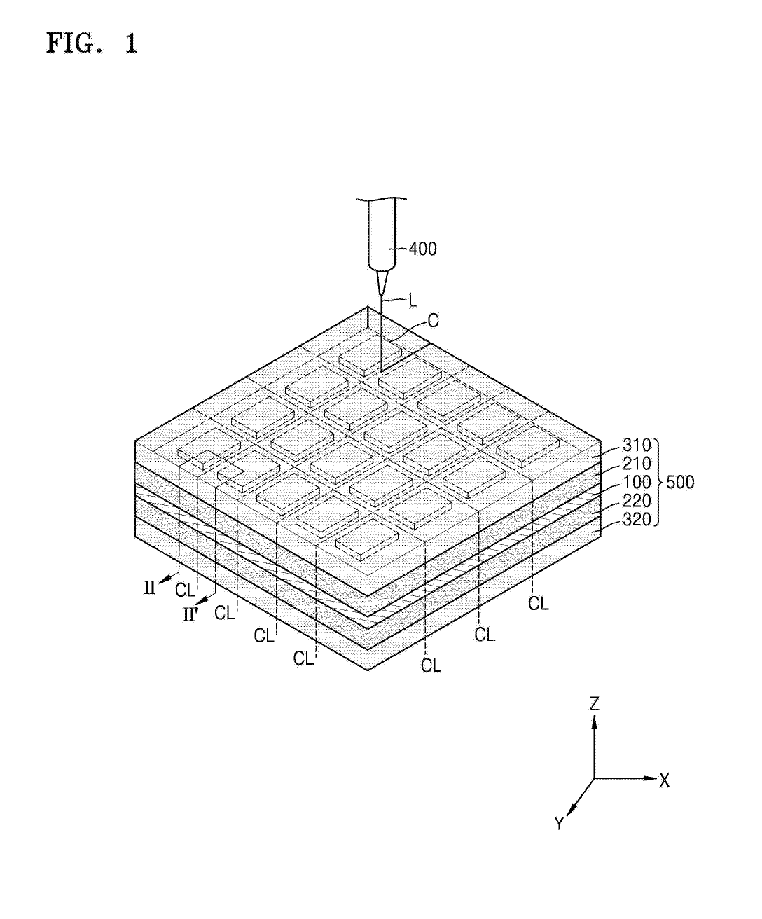

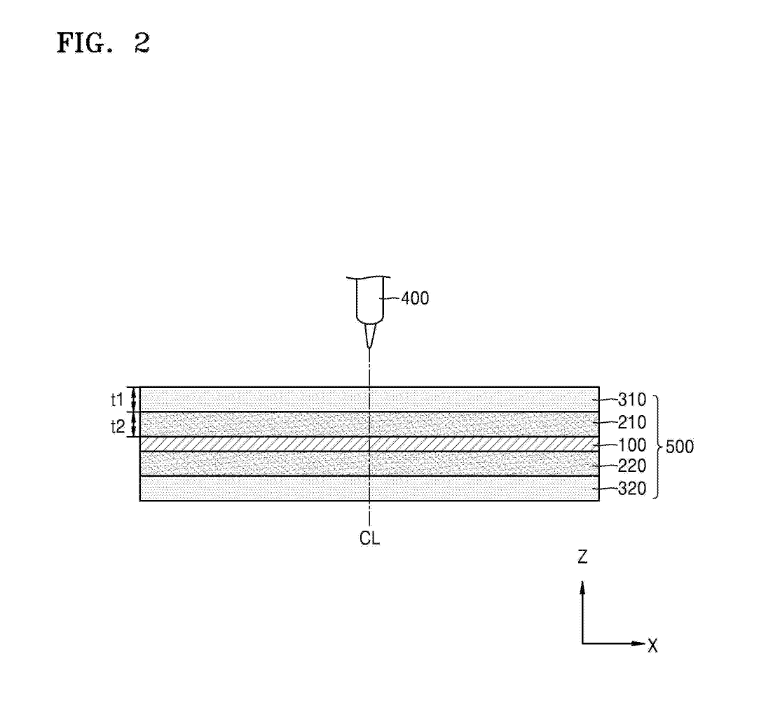

FIG. 1 is a perspective view schematically illustrating a flexible display in a mother substrate form before cutting the flexible display according to an embodiment, and FIG. 2 is a cross-sectional view taken along a line II-II of FIG. 1.

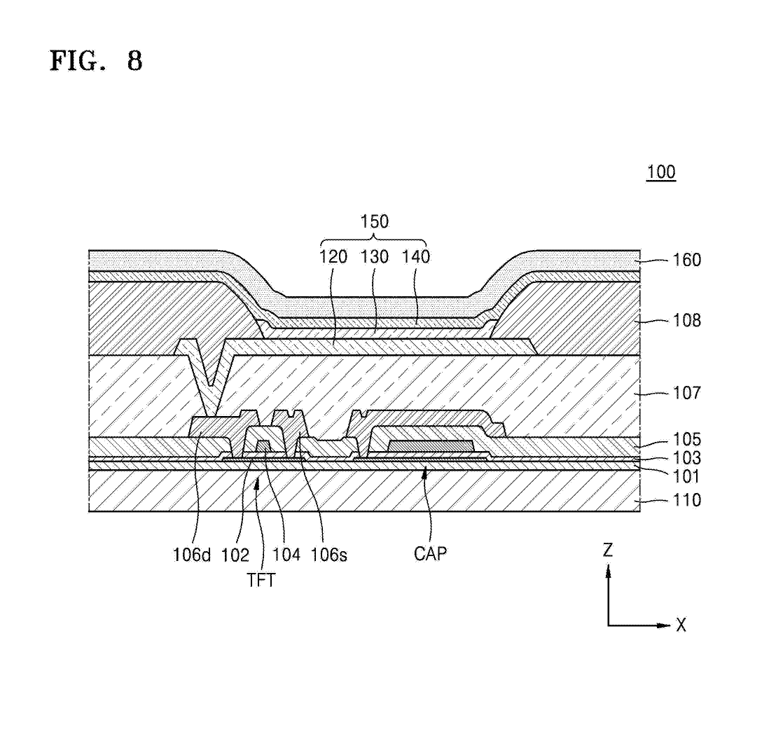

Referring to FIGS. 1 and 2, a manufacturing method of the flexible display includes forming a display panel 100 on a support substrate (not illustrated). Although the drawings illustrate the display panel 10 separated from the support substrate, since a flexible substrate 110 of FIG. 8 has a characteristic of rigidity enough to support the display panel 100, the display panel 100 may be formed on the support substrate having rigidity enough to support them during a manufacturing process. The display panel 100 may have one side and the other side opposite to the one side. A plurality of cells C each having a display unit are formed on the one side, and the other side may be a surface that contacts the support substrate.

Although not illustrated in the drawings, a manufacturing process of the display panel 100 includes forming the flexible substrate 110 on the support substrate. A sacrificial layer (not illustrated) may be formed between the support substrate and the flexible substrate 110 depending on the embodiment. The sacrificial layer may facilitate separation of the display panel 100 from the support substrate when the display panel 100 is separated from the support substrate after the display panel 100 is formed on the support substrate. The sacrificial layer may include various materials according to a separation process of separating the display panel 100 from the support substrate.

The display panel 100 may include the cells C each having the display unit. The display unit may be a liquid crystal display unit or an organic light-emitting display unit. This disclosure explains the organic light-emitting unit as an example. The cells C are formed as a mother substrate, as illustrated in FIG. 1. As such, the cells C are formed at once and then cut to be provided to each flexible display. A detail structure of the display panel 100 will be explained in the descriptions of FIG. 8 later.

As such, after the display panel 100 is formed, the method may include attaching a first protection film 310 to a side of the display panel 100. The first protection film 310 may have a first thickness t1. The first thickness t1 may be in a range from about 10 μm to about 100 μm. The first protection film 310 may include one material among polyethylene terephthalate (PET), polyethylene naphthalate (PEN), polyethylene sulfide (PES), and polyethylene (PE).

Here, a first adhesive layer 210 may be formed between the display panel 100 and the first protection film 310. The first adhesive layer 210 may be directly formed on one side of the display panel 100 or may include the first protection film 310 in a single body. When the first adhesive layer 210 is formed with the first protection film 310 in a single body, the first adhesive layer 210 may be disposed to face the one side of the display panel 100 to attach the first protection film 310 to the one side of the display panel 100.

The first adhesive layer 210 may include an absorber to absorb light of a first wavelength. Here, the first wavelength may be the same wavelength used in a cell cutting process using a laser L of a laser apparatus 400 (which will be described later). In the present embodiment, the first wavelength may be a wavelength in an ultraviolet (UV) range, or a wavelength in an infrared range.

The first adhesive layer 210 may include silicone, urethane, or acryl-based adhesive material. The first adhesive layer 210 can have an adhering force between an upper adhering force and a lower adhering force since the first adhesive layer 210 maintains an attached state during a process including attaching a thin film encapsulation layer 160 of FIG. 8 to the display panel 100 and since a different functional layer is attached after the first adhesive layer 210 is removed when the cell cutting process (which will be described later) is finished. The first adhesive layer 210 may have an adhering force of about 1 gf/in to about 50 gf/in. The above range can avoid or minimize the first adhesive layer 210 peeling off or detaching at a peripheral portion thereof during the process. Furthermore, the above range can avoid damage (for example, surface film detachment) on the thin film encapsulation layer during the removing of the first protection film 310. However, depending on the embodiment, the first adhesive layer 210 can have an adhering force less than about 1 gf/in or greater than about 50 gf/in.

The first adhesive layer 210 may have a second thickness t2. The second thickness t2 of the first adhesive layer 210 may be greater than the first thickness t1 of the first protection film 310. For example, the second thickness t2 of the first adhesive layer 210 may be about 10 μm to about 200 μm.

Thereafter, the display panel 100 is separated from the support substrate. In the process of separating the display panel 100 from the support substrate, the first protection film 310 may function to protect components disposed on the one side of the display panel 100 from being damaged. A method of separating the display panel 100 from the support substrate may include a method using the laser L, a method using an etchant, a separating method using a physical detachment, or various methods conventionally known in this field.

A second protection film 320 may be attached to the other side of the display panel 100 separated from the support substrate. Since the display panel 100 separated from the support substrate has various components formed on the flexible panel 110, the display panel 100 may have a characteristic sensitive to an external environment. Accordingly, in the following process, the second protection 320 may be attached to the other side of the display panel 100 to protect the display panel 100. The second protection film 320 may protect the flexible substrate 110 of the display panel 100 from being damaged after the display panel 100 is separated from the support substrate, and may function to prevent introduction of impurities into the flexible substrate 110.

The first protection film 320 may have the first thickness t1 in a range from about 10 μm to about 100 μm. The first protection film 310 may include one material among polyethylene terephthalate (PET), polyethylene naphthalate (PEN), polyethylene sulfide (PES), and polyethylene (PE).

Here, a second adhesive layer 220 may be formed between the display panel 100 and the second protection film 320. The second adhesive layer 220 may be directly formed on the other side of the display panel 100 or may include the second protection film 320 in an integrated body. When the second adhesive layer 220 is formed with the second protection film 320 in an integrated body, the second adhesive layer 220 may be disposed to face the other side of the display panel 100 to attach the second protection film 310 to the other side of the display panel 100. The second adhesive layer 220 may include silicone, urethane, or acryl-based adhesive material.

The second adhesive layer 220 may have the second thickness t2. The second thickness t2 of the second adhesive layer 220 may be greater than the first thickness t1 of the second protection film 320. For example, the second thickness t2 of the second adhesive layer 220 may be about 10 μtm to about 200 μm.

The second adhesive layer 220 may include an absorber to absorb light of the first wavelength. Here, the first wavelength may be the same wavelength used in a cell cutting process using the laser L of the laser apparatus 400 (which will be described later). In the present embodiment, the first wavelength may be a wavelength in an ultraviolet range, or a wavelength in an infrared range.

As such, a display panel assembly 500 may include the display panel 100 having the first protection film 310 and the first adhesive layer 210 attached to the one side of the display panel 100 and the second protection film 320 and the second adhesive layer 220 attached to the other side of the display panel 100. The cells C formed on the display panel 100 may be cut by irradiating the laser L on the display panel assembly 500. The cutting of the display panel 100 may include cutting along cutting lines CL formed between the cells C.

The laser L used in the cutting process of the display panel 100 may have the first wavelength. The first wavelength may be the same wavelength of the light absorbed by the absorber of the first adhesive layer 210 and the second adhesive layer 220. That is, if the laser L to cut the display panel 100 is the laser L having a wavelength in the ultraviolet range, the absorber included in the first adhesive layer 210 and the second adhesive layer 220 may be an absorber to absorb the light of the wavelength in the ultraviolet range. In other embodiments, if the laser L to cut the display panel 100 is the laser having a wavelength in the infrared range, the absorber of the first adhesive layer 210 and the second adhesive layer 220 may be an absorber to absorb the light of the wavelength in the infrared range.

Although FIGS. 1 and 2 illustrate that the laser L is irradiated in a direction from the first protection film 310 toward the second protection film 320, that is, a -Z direction, the described technology is not limited thereto. That is, the laser L may be irradiated in a direction from the second protection film 320 toward the first protection film 310 in a +Z direction.

Referring to FIG. 2, the first protection film 310 may have the first thickness t1 and the first adhesive layer 210 may have the second thickness t2. In this case, the second thickness t2 may be substantially the same as or greater than the first thickness t1. As described above in the cutting process of the display panel 100 by irradiating the laser L, the laser L is irradiated on the first protection film 310. Like this, in the processing of the first protection film 310, the light transmitted through the first protection film 310 may process the first adhesive layer 210, and thus a processing time of the first adhesive layer 210 may be substantially shortened. Accordingly, when the first adhesive layer 210 does not have a sufficient thickness, during the processing of the first protection film 310, the first adhesive layer 210 may be processed in advance to generate fumes which do not escape from the first adhesive layer 210 to outside thereof and thus damage the display panel 100.

Accordingly, in the manufacturing method of the flexible display according to the present embodiment, the processing of the first adhesive layer 210 in advance during the processing of the first protection film 310 may be prevented by forming the thickness of the first adhesive layer 210 to be the same as or greater than the thickness of the first protection film 310.

Similarly, the second protection film 320 may have the same first thickness t1 as the first protection film 310, and the second adhesive layer 220 may have the same second thickness t2 as the first adhesive layer 210. When the laser L is irradiated from the second protection film 320 toward the first protection film 310 in the +Z direction, the first protection film 31, the first adhesive layer 210, and the display panel 100 are processed in order, and then the second adhesive layer 220 and the second protection film 320. By providing a sufficient thickness of the second adhesive layer 220, a processing speed and an absorbing rate of absorbing the laser L may be controlled, and impurities generated during the processing of the second adhesive layer 220 and the second protection film 320 may be prevented from being introduced into the display panel 100.

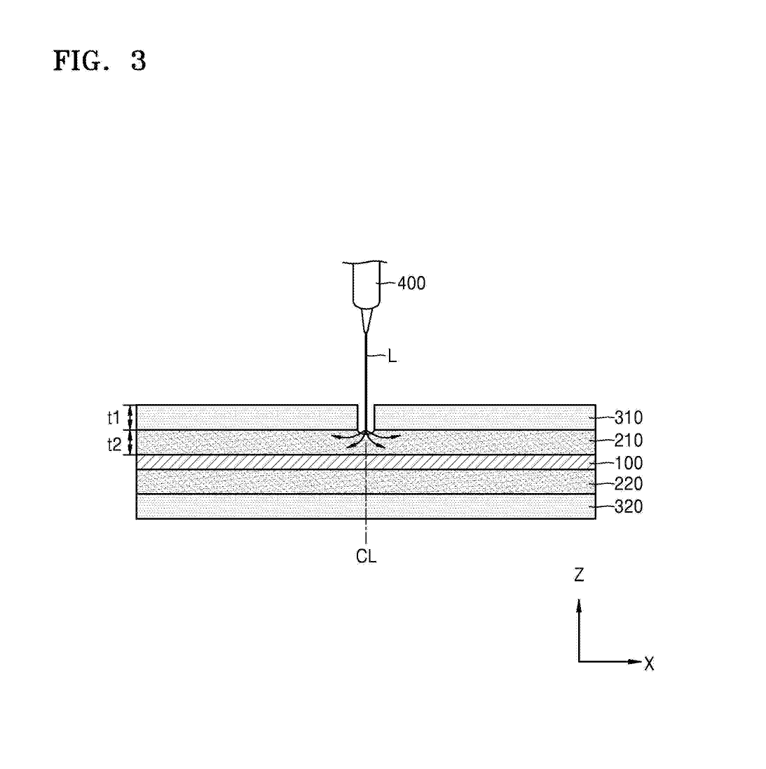

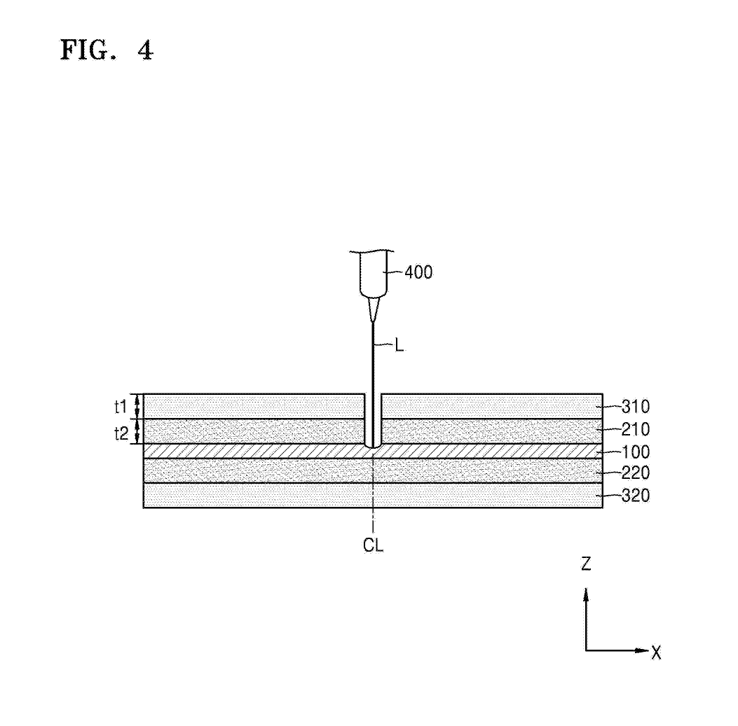

FIGS. 3 through 7 are cross-sectional views schematically illustrating a cutting process of a manufacturing method of the flexible display, according to an embodiment. The process of irradiating the laser L to cut the display panel 100 will be explained in detail with reference to FIGS. 3 through 7.

Referring to FIGS. 3 through 7, the laser L having the first wavelength is irradiated on the first protection film 310 to perform the process of cutting the first protection film 310. Thereafter, the laser L having the first wavelength is irradiated on the first adhesive layer 210 to perform the process of cutting the first adhesive layer 210.

During the cutting of the first protection film 310, a portion of the laser L having the first wavelength may transmit through the first protection film 310. For example, a transmittance may be over about 60% experimentally when the first protection film 310 includes polyethylene terephthalate PET and the wavelength of the laser L has a wavelength in the ultraviolet range. That is, about 60% of the laser L may transmit through the first protection film 310 to process the first adhesive layer 210 when the laser L processes the first protection film 310.

If an adhesive layer includes an adhering material without an absorber, since a processing time of the adhesive layer is shorter than the first protection film 310, the adhesive layer is processed in advance before the completion of the cutting process of the first protection film 310, to start the processing of the display panel 100. Since this phenomenon is generated before the completion of the processing of the first protection film 310, a passage may not be provided for impurities and fumes generated during the processing of the display panel 100 to escape to the outside, and thus the impurities and fumes may stay inside the display panel 100 to contaminate the display panel 100.

In the manufacturing method of the flexible display, according to an embodiment, an absorber to absorb light having the same wavelength of the laser L to cut the display panel 100 is added to the first adhesive layer 210. Accordingly, as illustrated in FIG. 3, the laser L transmitting through the first protection film 310 may be absorbed by the first adhesive layer 210 during the cutting of the first protection film 310. The first adhesive layer 210 may have a transmittance of about 0.1% to about 1% with respect to the laser L having the first wavelength. That is, since the laser L having the first wavelength has a lower transmitting ratio in transmitting through the first adhesive layer 210, the phenomenon of contaminating the display panel 100 due to the processing of the display panel 100 in advance before the first protection film 310 and the first adhesive layer 210 are completely processed may be significantly reduced.

For example, when the first wavelength is a wavelength in the ultraviolet range, the absorber may be a material among a benzotriazole-based ultraviolet absorber, a hydroxyphenyl triazine-based ultraviolet absorber, a benzophenone-based ultraviolet absorber, and a benzoate-based ultraviolet absorber. Particularly, 2,4-dihydroxybenzophenone, 2-hydroxy-4-methoxybenzophenone, or 2-hydroxy-4-n-(octyloxy)benzophenone may be usable as the absorber, but the present inventive concept is not limited thereto. In other embodiments, when the first wavelength is a wavelength in the infrared range, the absorber may be an infrared absorber.

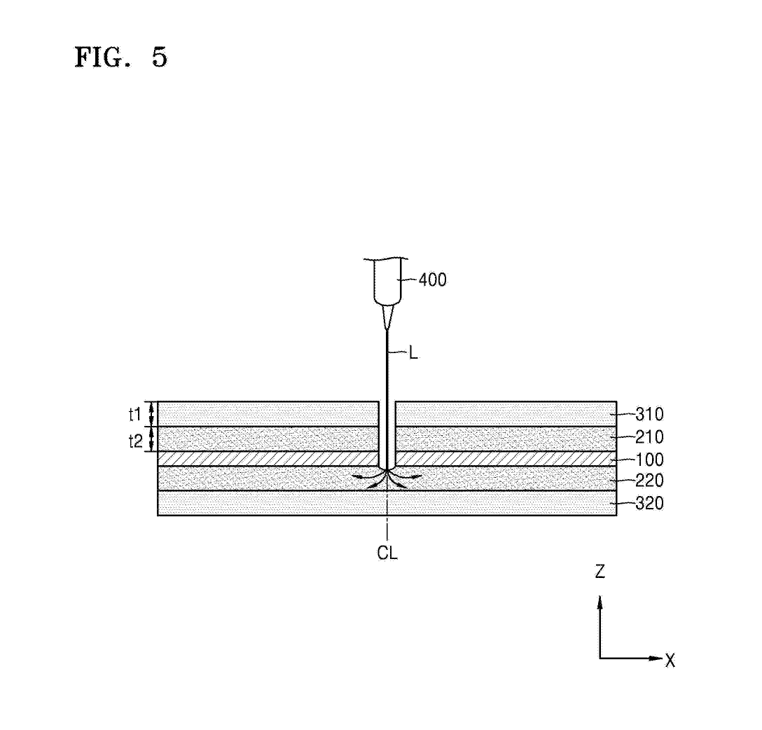

Referring to FIG. 5, the laser L having the first wavelength is irradiated on the display panel 100 to perform the cutting of the display panel 100. As illustrated in FIG. 1, the cutting of the display panel 100 may include cutting the cells C by irradiating the laser L on an area between the cells C. Although not illustrated in the drawings, the display unit is not formed on the cutting lines CL.

During the processing of the display panel 100, a portion of the laser L transmitting through the display panel 100 may be absorbed by the second adhesive layer 220. The portion of the laser L absorbed by the second adhesive layer 220 may shorten a processing time of the second adhesive layer 220.

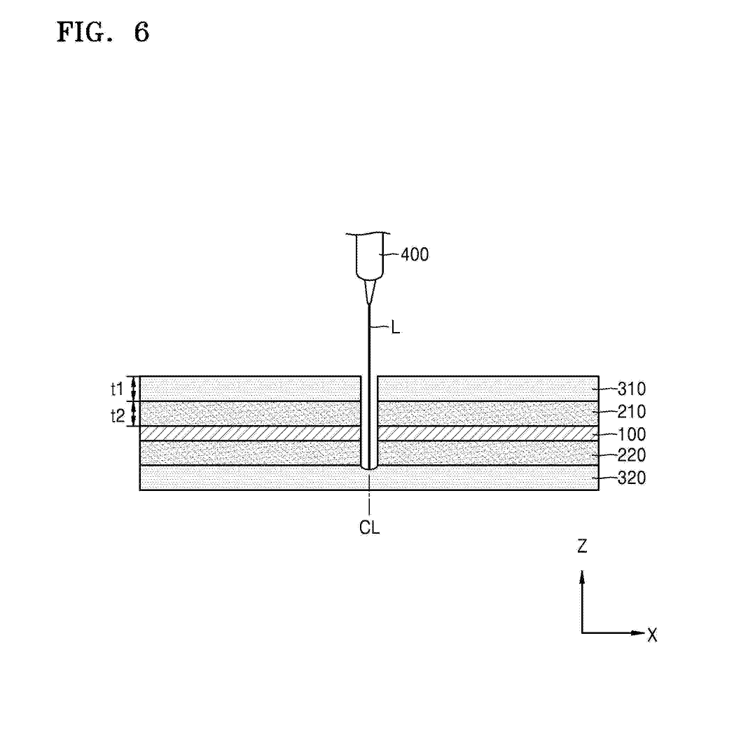

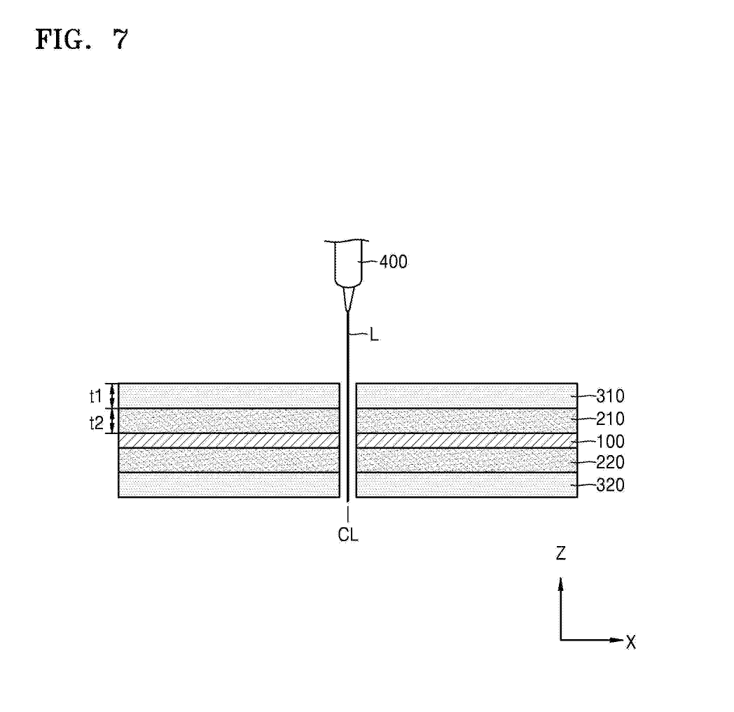

Thereafter, referring to FIGS. 6 and 7, the laser L having the first wavelength is irradiated on the second adhesive layer 220 to perform a process of cutting the second adhesive layer 220. Then, the laser L having the first wavelength is irradiated on the second protection film 320 to perform a process of cutting the second protection film 320. During the processing of the second adhesive layer 220 and the second protection film 320 after the first protection film 310, the first adhesive layer 210, and the display panel 100 are processed in order, since the second adhesive layer 220 includes an absorber to absorb light having the first wavelength, a processing time and an absorption rate of the laser L are controlled, and impurities generated during the processing of the second adhesive layer 220 and the second protection film 320 may be prevented from being introduced into the display panel 100.

FIG. 8 is an enlarged cross-sectional view illustrating an internal structure of the display panel 100 of the flexible display according to an embodiment.

The flexible substrate 110 may have excellent thermal resistance and durability and/or may have a flexible characteristic to realize a curved surface. The flexible substrate 110 may include various materials including a metal or a plastic material, for example, polyethylene terephthalate (PET), polyethylene naphthalate (PEN), or polyimide.

A thin film transistor TFT may be formed on the flexible substrate 110. The thin film transistor TFT may include a semiconductor layer 102 including amorphous silicon, polysilicon, or an organic semiconductor material, a gate electrode 104, a source electrode 106s, and a drain electrode 106d. A general structure of the thin film transistor TFT will be explained in detail hereinafter.

A buffer layer 101 including silicon oxide or silicon nitride is formed on the flexible substrate 110 to flatten a surface of the flexible substrate 110 or prevent introduction of impurities into the semiconductor layer 102 of the thin film transistor TFT. The semiconductor layer 102 is formed on the buffer layer 101.

The gate electrode 104 is formed on an upper side of the semiconductor layer 102 to electrically connect the source electrode 106s and the drain electrode 106d to each other according to a signal applied to the gate electrode 104. The gate electrode 104 may have adhesiveness with adjacent layers, surface flatness of the stacked layer, and workability, and thus may include a single layer or a multilayer including at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

A gate insulation layer 103 including silicon oxide and/or silicon nitride may be formed between the semiconductor layer 102 and the gate electrode 104 to provide insulating property of the semiconductor layer 102 and the gate electrode 104.

An interlayer insulation layer 105 may be formed on the gate electrode 104 and may have a single layer or a multilayer including a material of silicon oxide or silicon nitride.

The source electrode 106s and the drain electrode 106d are formed on the interlayer insulation layer 105. The source electrode 106s and the drain electrode 106d are electrically connected to the semiconductor layer 102 through a contact hole formed in the interlayer insulation layer 105 and the gate insulation layer 103. The source electrode 106s and the drain electrode 106d have conductivity and may have a single layer or a multilayer including at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

Although not illustrated in the drawings, a protection layer (not illustrated) may be formed to cover the thin film transistor to protect the thin film transistor having the above-described structure. The protection layer may include an inorganic compound such as silicon oxide, silicon nitride, or silicon oxynitride.

A first insulation layer 107 may be formed on the flexible substrate 110. In this case, the first insulation layer 107 may be a planarization layer or a protection layer. The first insulation layer 107 flattens an upper surface of the thin film transistor TFT and protects the thin film transistor TFT and various components when an organic light-emitting device is formed on the thin film transistor TFT. The first insulation layer 107 may include, for example, an acryl-based organic compound or benzocyclobutene (BCB). Here, the buffer layer 101, the gate insulation layer 103, the interlayer insulation layer 105, and the first insulation layer 107 may be formed on the entire area of the flexible substrate 110.

A second insulation layer 108 may be formed on an upper side of the thin film transistor TFT. In this case, the second insulation layer 108 may be a pixel-defining layer. The second insulation layer 108 may be disposed on the first insulation layer 107 and may have an opening. The second insulation layer 108 may define a pixel area on the flexible substrate 110.

The second insulation layer 108 may be an organic insulation layer, for example. The organic insulation layer may include acrylic polymer such as poly(methyl methacrylate) (PMMA), polystyrene PS, polymer derivative having a phenol group, imide polymer, acryl ester-based polymer, amide-based polymer, fluorine-based polymer, p-xylene polymer, vinyl alcohol polymer, and/or a mixture thereof.

An organic light-emitting device 150 may be formed on the second insulation layer 108. The organic light-emitting device 150 may include a pixel electrode 120, an intermediate layer 130 including an emission layer EML, and an opposite electrode 140.

The pixel electrode 120 may be a semi-transparent electrode or a reflective electrode. When the pixel electrode 120 is a semi-transparent electrode, the pixel electrode 120 may be indium tin oxide (ITO), indium zinc oxide (IZO), zinc oxide (ZnO), indium oxide (In₂O₃), indium gallium oxide (IGO) or aluminum zinc oxide (AZO). When the pixel electrode 120 is a reflective electrode, the pixel electrode 120 may include a reflective layer including silver (Ag), magnesium (Mg), aluminum (Al), platinum (Pt), palladium (Pd), gold (Au), Nickel (Ni), Neodymium (Nd), Iridium (Ir), chromium (Cr), and/or a mixture thereof, and a layer having indium tin oxide (ITO), indium zinc oxide (IZO), zinc oxide (ZnO), indium oxide (In₂O₃), indium gallium oxide (IGO) or aluminum zinc oxide (AZO). The present inventive concept is not limited thereto. Various materials may be usable, and a structure thereof may be variously changed to, for example, a single layer or a multilayer.

The intermediate layer 130 may be disposed in the pixel area defined by the second insulation layer 108. The intermediate layer 130 may include an emission layer EML to emit light according to an electrical signal. In addition to the emission layer EML, the intermediate layer 130 may be a single layer or a complex structure stack including a hole injection layer HIL disposed between the emission layer EML and the pixel electrode 210, a hole transport layer HTL and an electron transport layer ETL disposed between the emission layer EML and the opposite electrode 140, or an electron injection layer. However, the intermediate layer 130 is not limited thereto, and the intermediate layer 130 may have various structures.

The opposite electrode 140 covering the intermediate layer 130 including the emission layer EML and disposed opposite to the pixel electrode 120 may be formed on an entire area of the flexible substrate 110. The opposite electrode 140 may be a (semi-) transparent electrode or a reflective electrode.

When the opposite electrode 140 is a semi-transparent electrode, the opposite electrode 140 may include a layer including lithium (Li), calcium (Ca), lithium fluoride calcium (LiF/Ca), lithium fluoride aluminum (LiF/Al), aluminum (Al), silver (Ag), magnesium (Mg), or a mixture thereof, and a (semi-) transparent conductive layer of indium tin oxide (ITO), indium zinc oxide (IZO), zinc oxide (ZnO), or indium oxide (In₂O₃). When the opposite electrode 140 is a reflective electrode, the opposite electrode 140 may include a layer including lithium (Li), calcium (Ca), lithium fluoride calcium (LiF/Ca), lithium fluoride aluminum (LiF/Al), aluminum (Al), silver (Ag), magnesium (Mg), or a mixture thereof. However, a structure and a material of the opposite electrode 140 are not limited thereto, and they may be variously changed.

The encapsulation layer 160 may be further disposed on the flexible substrate 110 to cover the opposite electrode 140. Although not illustrated in the drawings, the encapsulation layer 160 may be a multilayer stack including at least one inorganic layer and an organic layer. The encapsulation layer 160 may prevent introduction of moisture or impurities into the display panel 100 and seal the organic light-emitting device 150.

As described above, the manufacturing method of the flexible display is explained. However, the described technology is not limited thereto. For example, a flexible display manufactured by the above-described manufacturing method of the flexible display is also within the scope of the present inventive concept.

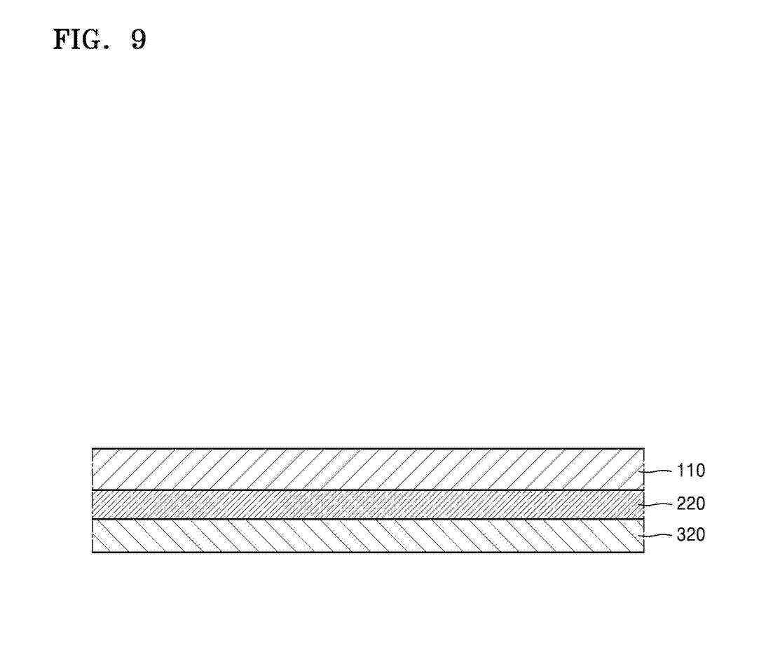

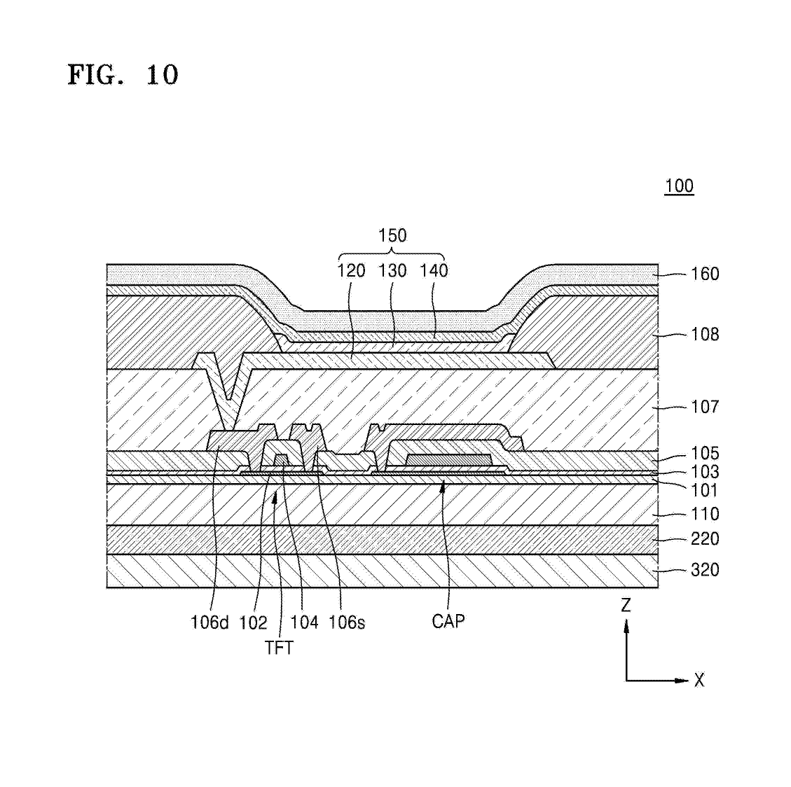

FIG. 9 is a cross-sectional view schematically illustrating a flexible display according to an embodiment, and FIG. 10 is a cross-sectional view illustrating a structure of the display panel 100 of the flexible display of FIG. 9 in detail.

Referring to FIGS. 9 and 10, the flexible display according to an embodiment includes the flexible substrate 110, the thin film transistor and light-emitting device disposed on the flexible substrate 110, and an adhesive layer disposed between the flexible substrate 110 and a protection film.

The flexible substrate 110 has two opposing sides. The flexible substrate 110 has excellent thermal resistance and durability and/or has a flexible characteristic to realize a curved surface. The flexible substrate 110 includes various materials, for example, a metal or a plastic material such as polyethylene terephthalate (PET), polyethylene naphthalate (PEN), and polyimide.

The thin film transistor TFT and an organic light-emitting device electrically connected to the thin film transistor TFT may be disposed on the one side of the flexible substrate 110. The light-emitting device may be a liquid crystal device or an organic light-emitting device. In this present embodiment, the organic light-emitting device is illustrated and explained as the light-emitting device.

The thin film transistor TFT may include a semiconductor layer 102 including amorphous silicon, polysilicon, or an organic semiconductor material, a gate electrode 104, a source electrode 106s, and a drain electrode 106d. A general structure of the thin film transistor TFT will be explained in detail hereinafter, and it described overlapping portion of FIG. 8 will be omitted.

On the flexible substrate 110, common layers, such as the buffer layer 101, the gate insulation layer 103, and the interlayer insulation layer 105, may be arranged in an entire area of the flexible substrate 110, the patterned semiconductor layer 102 including a channel area, a source contact area, and a drain contact area may be arranged, and the gate electrode 104, the source electrode 106s, and the drain electrode 106d as components of the thin film transistor TFT together with the patterned semiconductor layer 102 may be arranged.

The first insulation layer 107 having a flat upper surface covering the thin film transistor TFT may be disposed in the entire area of the flexible substrate 110. An organic light-emitting device (OLED) including the patterned pixel electrode 120, the opposite electrode 140 to correspond to the entire area of the flexible substrate 110, and the intermediate layer 130 disposed between the pixel electrode 120 and the opposite electrode 140a and having a multilayer structure with a light-emitting layer may be disposed on the first insulation layer 107. Although the intermediate layer 130 is illustrated above, a portion of layers may be a common layer to correspond to the entire area of the flexible substrate 110, or the other portion of the layers may be a patterned layer to correspond to the pixel electrode 120. The pixel electrode 120 may be electrically connected to the thin film transistor TFT through a via hole. The second insulation layer 10 may be disposed on the first insulation layer to correspond to the entire area of the flexible substrate 110 to cover a boundary of the pixel electrode 120 and have an opening to define each pixel area.

The thin film encapsulation layer 160 may be arranged on the flexible substrate 110 to cover the opposite electrode 140. Although not illustrated, the thin film encapsulation layer 160 may be a multilayer structure stack including at least one inorganic layer and one organic layer. The thin film encapsulation layer 160 may prevent introduction of oxygen, moisture, and impurity into the display panel 100 and may seal the organic light-emitting device 150 from an outside thereof.

The second protection film 320 may be disposed on the other side of the flexible substrate 110. Since the display panel 100 separated from the support substrate in the manufacturing process may be in a shape formed with various components disposed on the flexible substrate 110, the flexible substrate 110 may have a characteristic sensitive to an external environment. Accordingly, in the following process, the second protection film 320 may be attached to the other side of the flexible substrate 110 to protect the display panel 100.

The second protection film 320 prevents the flexible substrate 110 of the display panel 100 from being damaged and prevents introduction of impurities into the flexible substrate 110.

The second protection film 320 may have the first thickness t1, and the first thickness t1 may be about 10 μm to about 100 μm, for example. The protection film 340 may include a material among polyethylene terephthalate (PET), polyethylene sulfide (PES), and polyethylene (PE).

The second adhesive layer 220 may be formed between the flexible substrate 110 and the protection film 320. The second adhesive layer 220 may have the second thickness T2. The second thickness t2 may be greater than the first thickness t1 of the second protection film 320. For example, the second thickness t2 may be about 10 μm to about 200 μm.

The second adhesive layer 220, according to one disclosed embodiment, includes an absorber to absorb light of the first wavelength. Here, the first wavelength may be a same wavelength used in a cell cutting process using the laser L of the laser apparatus 400. In the present embodiment, the first wavelength may be a wavelength in an ultraviolet range, or a wavelength in an infrared range. For example, in case of the wavelength in the ultraviolet range, the wavelength may be 343 nm or 355 nm, for example.

The second adhesive layer 220 may include silicone, urethane or acryl-based adhesive material. That is, the second adhesive layer 220 may be a combination of silicone, urethane or acryl-based adhesive material and an absorber to absorb the wavelength in the ultraviolet range and the wavelength in the infrared range. Accordingly, the second adhesive layer 220 may have the transmittance of about 0.1% to about 1% with respect to light having a wavelength in an ultraviolet range or the wavelength in an infrared range.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details may be made therein without departing from the spirit and scope as defined by the following claims.

What is claimed is:

1. A method of manufacturing a flexible display, the method comprising:
forming a display panel including first and second sides opposing each other, wherein the display panel includes a plurality of cells in a mother substrate form, and wherein each of the cells includes a display unit;
attaching a first protection film on the first side of the display panel via a first adhesive layer;
attaching a second protection film on the second side of the display panel via a second adhesive layer; and
irradiating laser light having a first wavelength between the cells so as to cut the display panel into the cells,
wherein each of the first and second adhesive layers includes an absorber configured to absorb light having the first wavelength.

2. The method of claim 1, wherein the irradiating comprises:
irradiating laser light having the first wavelength on the first protection film so as to cut the first protection film;
irradiating laser light having the first wavelength on the first adhesive layer so as to cut the first adhesive layer;
irradiating laser light on an area between the cells so as to cut the cells;
irradiating laser light having the first wavelength on the second adhesive layer; so as to cut the second adhesive layer; and
irradiating laser light having the first wavelength on the second protection film so as to cut the second protection film.

3. The method of claim 1, wherein each of the first and second protection films has a first thickness, and wherein each of the first and second adhesive layers has a second thickness that is the same as or greater than the first thickness.

4. The method of claim 3, wherein the first thickness is about 10 μm to about 100 μm, and wherein the second thickness is about 10 μm to about 200 μm.

5. The method of claim 1, wherein each of the first and second adhesive layers comprises silicone, urethane, or acryl-based adhesive material.

6. The method of claim 1, wherein the first wavelength is a wavelength in an ultraviolet (UV) range.

7. The method of claim 1, wherein the first wavelength is a wavelength in an infrared (IR) range.

8. The method of claim 1, wherein each of the first and second adhesive layers has a transmittance of about 0.1% to about 1% with respect to light having the first wavelength.

9. The method of claim 1, wherein each of the first and second protection films comprises at least one of the following: polyethylene terephthalate (PET), polyethylene naphthalate (PEN), polyethylene sulfide (PES), and polyethylene (PE).

10. A flexible display comprising:
a flexible substrate including first and second sides opposing each other;
a thin film transistor disposed on the first side of the flexible substrate and a light-emitting device electrically connected to the thin film transistor;
a protection film disposed on the second side of the flexible substrate; and
an adhesive layer disposed between the flexible substrate and the protection film, wherein the adhesive layer includes an absorber configured to absorb light having a first wavelength.

11. The flexible display of claim 10, wherein the first wavelength is a wavelength in the ultraviolet (UV) spectrum.

12. The flexible display of claim 10, wherein the first wavelength is a wavelength in the infrared (IR) spectrum.

13. The flexible display of claim 10, wherein the protection film has a first thickness and wherein the adhesive layer has a second thickness that is the same as or greater than the first thickness.

14. The flexible display of claim 13, wherein the first thickness is about 10 μm to about 100 μm, and wherein the second thickness is about 10 μm to about 200 μm.

15. The flexible display of claim 10, wherein the adhesive layer comprises silicone, urethane, or acryl-based adhesive material.

16. The flexible display of claim 10, wherein the adhesive layer has transmittance of about 0.1% to about 1% with respect to light having the first wavelength.

17. The flexible display of claim 10, wherein the protection film comprises at least one of the following: polyethylene terephthalate (PET), polyethylene naphthalate (PEN), polyethylene sulfide (PES), and polyethylene (PE).

18. A flexible display comprising:
a flexible substrate including first and second sides opposing each other;
a protection film disposed on the second side of the flexible substrate; and
an adhesive layer disposed between the flexible substrate and the protection film, wherein the adhesive layer includes an absorber configured to absorb light having a non-visible light wavelength.

19. The flexible display of claim 18, wherein the protection film has a first thickness and wherein the adhesive layer has a second thickness that is the same as or greater than the first thickness.

20. The flexible display of claim 19, wherein the first thickness is about 10 μm to about 100 μm, and wherein the second thickness is about 10 μm to about 200 μm.
